(19) United States
(12) Patent Application Publication
(10) Pub. No.: US 2025/0261409 A1
(43) Pub. Date: Aug. 14, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventors: Won Geun CHOI, Gyeonggi-do (KR); Rho Gyu KWAK, Gyeonggi-do (KR); Na Yeong YANG, Gyeonggi-do (KR); Jung Shik JANG, Gyeonggi-do (KR); Seok Min CHOI, Gyeonggi-do (KR)

(21) Appl. No.: 18/660,229

(22) Filed: May 10, 2024

(30) Foreign Application Priority Data
Feb. 8, 2024 (KR) 10-2024-0019942

(51) Int. Cl. H01L 29/423; H01L 29/417; H01L 29/788

(52) U.S. Cl. CPC H10D 30/694; H10D 30/68; H10D 64/258

(57) ABSTRACT

A semiconductor device may include a gate structure including stacked gate lines, a first contact plug extending through the gate structure, electrically connected to a first gate line among the gate lines, and including a first portion having a taper shape and a second portion having an inverted taper shape, and a second contact plug extending through the gate structure, electrically connected to a second gate line among the gate lines, and having a taper shape.

### CROSS-REFERENCE TO RELATED APPLICATION

This application claims priority under 35 U.S.C. § 119 to Korean Patent Application No. 10-2024-0019942 filed on Feb. 8, 2024, which is incorporated herein by reference in its entirety.

### BACKGROUND

### 1. Technical Field

Embodiments of the present disclosure relate to an electronic device and, more particularly, to a semiconductor device and a method of manufacturing the semiconductor device.

### 2. Related Art

The integration degree of a semiconductor device also known as component density or functionality density is mainly determined by the region occupied by a unit memory cell. Hence, higher integration degree generally means more components and/or higher functionality per chip. Recently, as improvement in the integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed to improve operation reliability of the semiconductor device.

### SUMMARY

According to an embodiment of the present disclosure, a semiconductor device may include a gate structure including a plurality of gate lines, a first contact plug extending through the gate structure, the first contact plug being electrically connected to a first gate line among the gate lines, and including a first portion having a taper shape and a second portion having an inverted taper shape, and a second contact plug extending through the gate structure, electrically connected to a second gate line among the gate lines, and having a taper shape.

According to an embodiment of the present disclosure, a semiconductor device may include a gate structure including stacked gate lines, a source structure disposed on the gate structure, and a first contact plug extending through the gate structure and the source structure, the first contact plug being electrically connected to a first gate line among the gate lines, and the first contact plug may include a first portion extending through the gate structure and having a taper shape, a second portion extending through the gate structure and having an inverted taper shape, and a third portion extending through the source structure and having a taper shape.

According to an embodiment of the present disclosure, a method of manufacturing a semiconductor device may include forming a sacrificial contact structure extending from a front surface of a first stack toward a rear surface, forming a second stack on the front surface of the first stack, forming a first opening by removing the sacrificial contact structure through the rear surface of the first stack, forming a second opening in the second stack by etching the second stack through the first opening, and forming a contact plug in the first opening and the second opening.

According to an embodiment of the present disclosure, a method of manufacturing a semiconductor device may include forming a first stack including first material layers and second material layers alternately stacked on a substrate, forming a sacrificial contact structure extending into the substrate through the first stack, forming a second stack including third material layers and fourth material layers alternately stacked on a front surface of the first stack, exposing a rear surface of the first stack by removing the substrate, forming a source structure on the rear surface of the first stack, forming an opening extending through the source structure and exposing the sacrificial contact structures, forming a first opening by removing the sacrificial contact structure through the opening, forming a second opening by etching the second stack through the opening and the first opening, and forming a contact plug in the opening, the first opening, and the second opening.

### BRIEF DESCRIPTION OF THE DRAWINGS

FIGS. 1A to 1C are simplified diagrams illustrating a structure of a semiconductor device according to an embodiment of the present disclosure.

FIGS. 2A to 2C are simplified diagrams illustrating a structure of a semiconductor device according to an embodiment of the present disclosure.

FIGS. 3A and 3B are simplified diagrams illustrating a structure of a semiconductor device according to an embodiment of the present disclosure.

FIGS. 4A to 4E are simplified diagrams illustrating a method of manufacturing a semiconductor device according to an embodiment of the present disclosure.

FIGS. 5A to 13A and 5B to 13B are simplified diagrams illustrating a method of manufacturing a semiconductor device according to an embodiment of the present disclosure.

FIG. 14 is a configuration diagram of a semiconductor device according to an embodiment of the present disclosure.

FIG. 15 is a configuration diagram of a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

An integration degree of a semiconductor device may be improved by stacking memory cells in a three dimension. In addition, a semiconductor device with a stable structure and improved reliability may be provided.

Hereinafter, embodiments according to the technical spirit of the present disclosure are described with reference to the accompanying drawings.

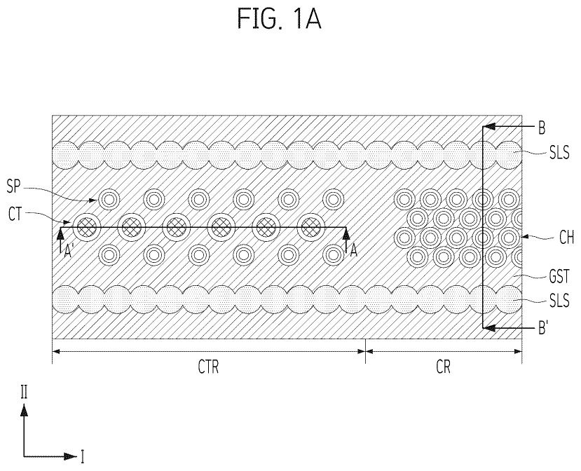

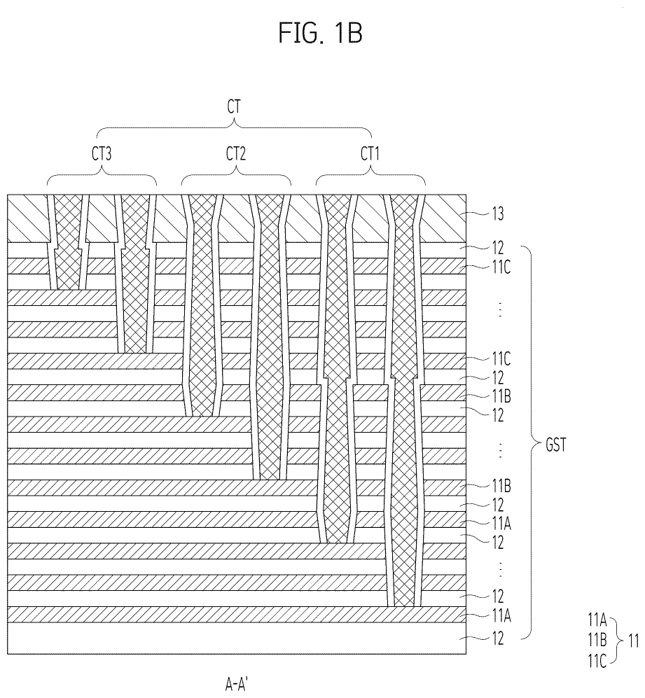

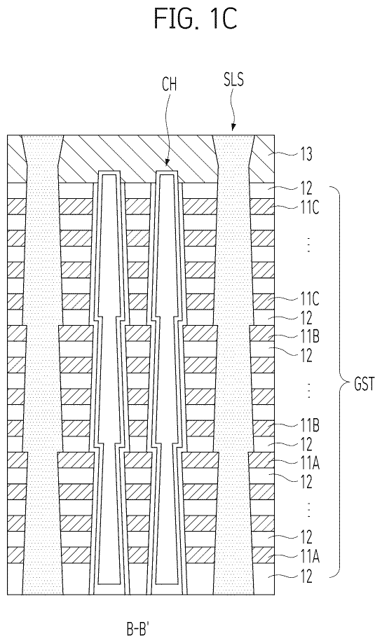

FIGS. 1A to 1C are simplified diagrams illustrating a structure of a semiconductor device according to an embodiment of the present disclosure. FIG. 1B is a cross-sectional view taken along a line A-A′ of FIG. 1A, and FIG. 1C is a cross-sectional view taken along a line B-B′ of FIG. 1A.

Referring to FIGS. 1A to 1C, the semiconductor device may include a gate structure GST and a plurality of contact plugs CT. The plurality of contact plugs CT may be spaced apart from each other at a regular interval. The semiconductor device may further include at least one of a source structure 13, a channel structure CH, a slit structure SLS, and a support SP.

The gate structure GST may include stacked gate lines 11. In an embodiment, the gate lines 11 and insulating layers 12 may be alternately stacked. For example, the gate lines 11 may be a select line, a word line, and the like. The gate lines 11 may include a conductive material such as polysilicon or metal. The insulating layers 12 may be for insulating the stacked gate lines 11 from each other. The insulating layers 12 may include an insulating material such as oxide or nitride, and may include a void therein.

The gate lines 11 may include first gate lines 11A, second gate lines 11B, and third gate lines 11C. The second gate lines 11B may be stacked on the first gate lines 11A, and the third gate lines 11C may be stacked on the second gate lines 11B.

The gate structure GST may include a cell region CR and a contact region CTR. The cell region CR may be a region where memory cells are stacked. The contact region CTR may be a region where an interconnection structure through which a bias for driving the stacked memory cells is transmitted is formed. The cell region CR and the contact region CTR may be adjacent to each other in a first direction I.

The channel structure CH may extend through the cell region CR of the gate structure GST. The channel structure CH may extend into the source structure 13 through the gate structure GST. The support SP may extend through the contact region CTR of the gate structure GST. The support SP may have a structure that is similar to the channel structure CH. The slit structure SLS may pass through the cell region CR of the source structure 13 and the gate structure GST and may extend in the first direction I. The slit structure SLS may extend to the contact region CTR. The gate structure GST may be positioned between the slit structures SLS which are adjacent to each other in the second direction II.

The contact plugs CT may be arranged in the contact region CTR of the gate structure GST and may extend into various depths inside the gate structure GST through the source structure 13. The contact plugs CT may include first to third contact plugs CT1, CT2, and CT3. The first contact plugs CT1 may be connected to first gate lines GL1, respectively. The second contact plugs CT2 may be connected to second gate lines GL2. The third contact plugs CT3 may be connected to third gate lines GL3. The first contact plugs CT1 may have a greater height than the height of the second contact plugs CT2. The second contact plugs CT2 may have a greater height than the height of the third contact plugs CT3.

According to the above structure, the contact plugs CT may extend into the gate structure GST. Also, the contact plugs CT and the gate lines 11 may be connected to each other in a one to one correspondence. As illustrated in FIG. 1B, each of the contact plugs may extend to a different depth inside the gate structure GST and connect with a different one of the gate lines 11. Therefore, even though the contact region CTR is not patterned in a step shape, a bias may be respectively applied to each of the gate lines 11.

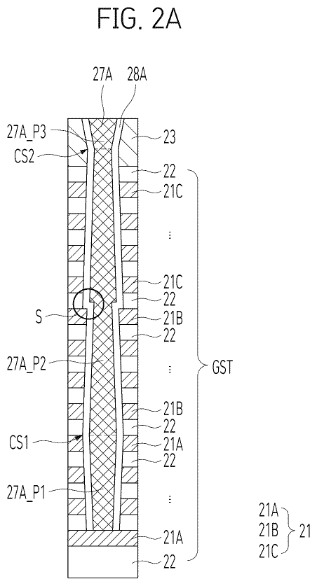

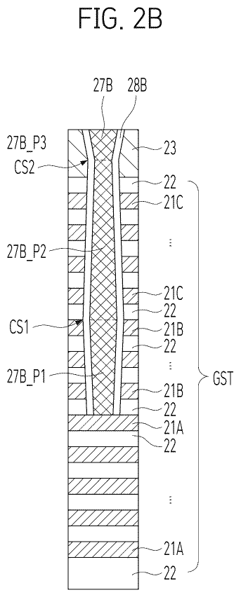

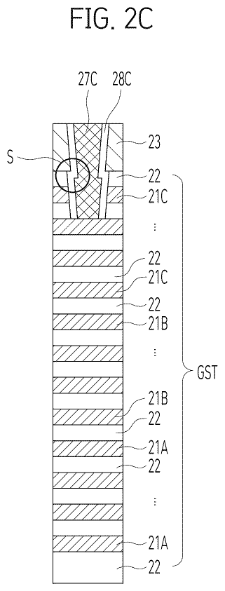

FIGS. 2A to 2C are simplified diagrams illustrating a structure of a semiconductor device according to an embodiment of the present disclosure. Hereinafter, any description that overlaps with what was described above may be omitted.

Referring to FIG. 2A, the semiconductor device may include a gate structure GST, a source structure 23, a first contact plug 27A, and a first insulating spacer 28A. The gate structure GST may include gate lines 21 and insulating layers 22 that are alternately stacked. The source structure 23 may be positioned over, or as illustrated in FIG. 2A, directly on the gate structure GST.

The first contact plug 27A may extend through the source structure 23 and the gate structure GST, and may be electrically connected to a first gate line 21A. A sidewall of the first contact plug 27A may be surrounded by the first insulating spacer 28A. A lower surface of the first contact plug 27A may be exposed by the first insulating spacer 28A and may be in contact with a corresponding first gate line 21A.

The first contact plug 27A may have a width that changes according to a level and may be divided into a plurality of portions according to a cross-sectional shape. The first contact plug 27A may include a first portion 27A_P1 and a second portion 27A_P2 connected to the first portion 27A_P1. An upper portion of the first portion 27A_P1 and a lower portion of the second portion 27A_P2 may be connected.

The first contact plug 27A may include a first connect surface CS1 of the first portion 27A_P1 and the second portion 27A_P2, and a width of the first portion 27A_P1 and the second portion 27A_P2 may decrease as a distance from the first connect surface CS1 increases. The first portion 27A_P1 may have a taper shape, and a lower width may be less than an upper width. The second portion 27A_P2 may have an inverted taper shape, and an upper width may be less than a lower width. The inverted taper shape may be repeated at least once, for example, two times in the second portion 27A_P2. As the inverted taper shape is repeated, the first contact plug 27A may include at least one step S on a sidewall. The second portion 27A_P2 may protrude into the source structure 23.

The first contact plug 27A may further include a third portion 27A_P3 connected to the second portion 27A_P2. The third portion 27A_P3 may extend through the source structure 23 and may have a taper shape. A lower width of the third portion 27A_P3 may be less than an upper width. The third portion 27A_P3 may have a height lower than that of the source structure 23, and a second connect surface CS2 of the second portion 27A_P2 and the third portion 27A_P3 may be positioned in the source structure 23. A width of the second portion 27A_P2 and the third portion 27A_P3 may increase as a distance from the second connect surface CS2 increases.

The semiconductor device may include a plurality of first contact plugs 27A. The plurality of first contact plugs 27A may be respectively connected to a plurality of first gate lines 21A, and the first contact plugs 27A may have different heights. In an embodiment, comparing the first contact plugs 27A having different heights with each other, heights of the second portions 27A_P2 may be the same, heights of the third portions 27A_P3 may be the same and heights of the first portions 27A_P1 may be different.

Referring to FIG. 2B, the semiconductor device may include the gate structure GST, the source structure 23, a second contact plug 27B, and a second insulating spacer 28B.

The second contact plug 27B may extend through the source structure 23 and the gate structure GST, and may be electrically connected to a second gate line 21B. A sidewall of the second contact plug 27B may be surrounded by the second insulating spacer 28B. A lower surface of the second contact plug 27B may be exposed by the second insulating spacer 28B and may be in contact with a corresponding second gate line 21B.

The second contact plug 27B may have a height lower than that of the first contact plug 27A. The second contact plug 27B may include a first portion 27B_P1, a third portion 27B_P3, and a second portion 27B_P2 connected between the first portion 27B_P1 and the third portion 27B_P3. An upper portion of the first portion 27B_P1 and a lower portion of the second portion 27B_P2 may be connected, and an upper portion of the second portion 27B_P2 and a lower portion of the third portion 27B_P3 may be connected. The first portion 27B_P1 and the third portion 27B_P3 may have a taper shape, and the second portion 27B_P2 may have an inverted taper shape.

The second contact plug 27B may include a first connect surface CS1 and a second connect surface CS2. A width of the first portion 27B_P1 and the second portion 27B_P2 may decrease as a distance from the first connect surface CS1 increases, and a width of the second portion 27B_P2 and the third portion 27B_P3 may decrease as a distance from the second connect surface CS2 increases.

The semiconductor device may include a plurality of second contact plugs 27B. The plurality of second contact plugs 27B may be respectively connected to a plurality of second gate lines 21B, and the second contact plugs 27B may have different heights. In an embodiment, comparing the second contact plugs 27B having different heights with each other, heights of the second portions 27B_P2 may be the same, heights of the third portions 27B_P3 may be the same and heights of the first portions 27B_P1 may be different.

Referring to FIG. 2C, the semiconductor device may include the gate structure GST, the source structure 23, a third contact plug 27C, and a third insulating spacer 28C. The third contact plug 27C may extend through the source structure 23 and the gate structure GST, and may be electrically connected to a third gate line 21C. The third insulating spacer 28C may surround a sidewall of the third contact plug 27C.

The third contact plug 27C may have a taper shape. A lower portion of the third contact plug 27C may have a width narrower than that of an upper portion. In an embodiment, the third contact plug 27C may have a structure in which a taper shape is repeated at least once. In this case, the third contact plug 27C may include at least one step S on a sidewall. The step S may be positioned to correspond to an interface of the source structure 23 and the gate structure GST.

The semiconductor device may include a plurality of third contact plugs 27C. The plurality of third contact plugs 27C may be respectively connected to the third gate lines 21C, and the third contact plugs 27C may have different heights.

According to the structure described above, the contact plugs 27A to 27C may have a structure in which the taper shape and the inverted taper shape are combined. The first contact plug 27A and the second contact plug 27B may have a structure in which the second portion of the inverted taper shape is positioned between the first portion and the third portion of the taper shape. The third contact plug 27C may have a structure in which the taper shape is repeated at least once.

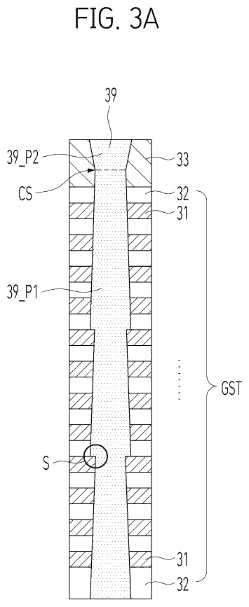

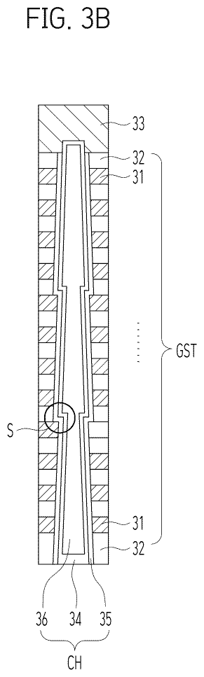

FIGS. 3A and 3B are simplified diagrams illustrating a structure of a semiconductor device according to an embodiment of the present disclosure. Hereinafter, any description that overlaps with what was described above may be omitted.

Referring to FIG. 3A, the semiconductor device may include a gate structure GST, a source structure 33, and a slit structure 39. The gate structure GST may include gate lines 31 and insulating layers 32 that are alternately stacked. The source structure 33 may be positioned over, or as illustrated in FIG. 3A, directly on the gate structure GST.

The slit structure 39 may pass through (also referred to as extend through) the source structure 33 and the gate structure GST. The slit structure 39 may include a first portion 39_P1 extending through the gate structure GST and a second portion 39_P2 extending through the source structure 33. An upper portion of the first portion 39_P1 and a lower portion of the second portion 39_P2 may be connected. The first portion 39_P1 may have an inverted taper shape, and the second portion 39_P2 may have a taper shape. The inverted taper shape may be repeated at least once, for example, two times in the first portion 39_P1. As the inverted taper shape is repeated, the slit structure 39 may include at least one step S on a sidewall. The first portion 39_P1 may protrude into the source structure 33.

The slit structure 39 may include a connect surface CS of the first portion 39_P1 and the second portion 39_P2. The connect surface CS may be positioned in the source structure 33. A width of the first portion 39_P1 and the second portion 39_P2 may increase as a distance from the connect surface CS increases.

The slit structure 39 may include a gap-fill material or may include a source contact structure. For example, the gap-fill material may include an insulating material such as oxide or nitride, or may include a semiconductor material such as silicon. The source contact structure may include a source contact plug electrically connected to the source structure 33 and an insulating spacer surrounding a sidewall of the source contact plug.

Referring to FIG. 3B, the semiconductor device may include the gate structure GST, the source structure 33, and a channel structure CH. The channel structure CH may extend into the source structure 33 through the gate structure GST. The channel structure CH may include a channel layer 34 and may further include at least one of a memory layer 35 and an insulating core 36. The channel layer 34 may protrude into the source structure 33 and may be connected to the source structure 33. The memory layer 35 may surround a sidewall of the channel layer 34 and may include at least one of a tunneling layer, a data storage layer, and a blocking layer. The data storage layer may include a floating gate, polysilicon, charge trap material, nitride, variable resistance material, and the like. The insulating core 36 may be positioned in the channel layer 34.

The channel structure CH may have an inverted taper shape, and the inverted taper shape may be repeated at least once, for example, two times. As the inverted taper shape is repeated, the channel structure CH may include steps S on a sidewall.

According to the structure described above, the slit structure 39 may have a structure in which the taper shape and the inverted taper shape are combined. The slit structure 39 may have a structure in which the first portion 39_P1 of the repeated inverted taper shape and the second portion 39_P2 of the taper shape are connected. The channel structure CH may have a structure in which the inverted taper shape is repeated at least once.

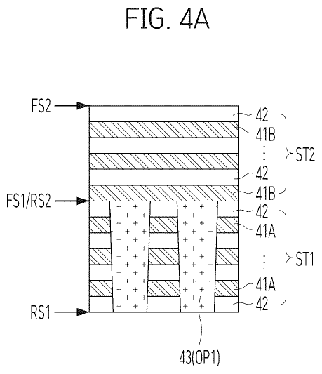

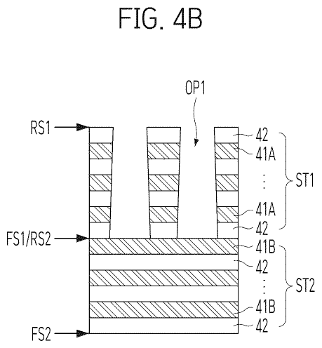

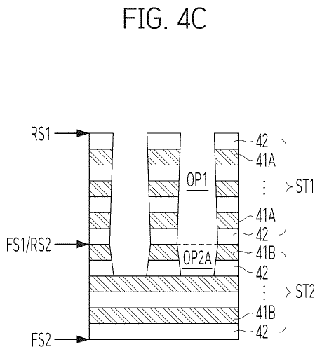

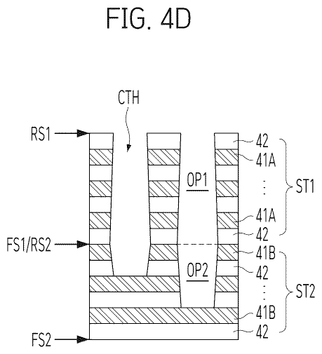

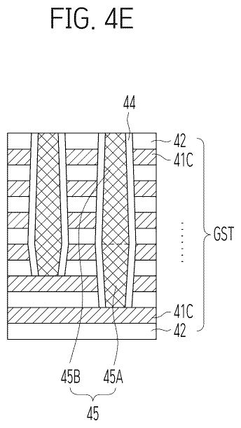

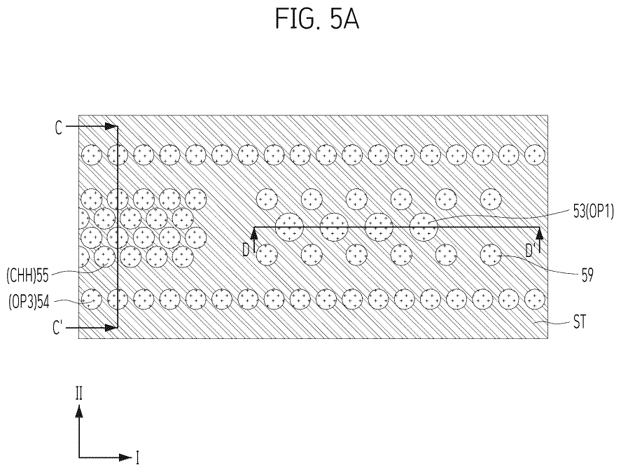

FIGS. 4A to 4E are simplified diagrams illustrating a method of manufacturing a semiconductor device according to an embodiment of the present disclosure. Hereinafter, any description that overlaps with what was described above may be omitted.

Referring to FIG. 4A, a first stack ST1 including first material layers 41A and insulating layers 42 alternately stacked may be formed. The first material layers 41A may include a material with a high etch selectivity with respect to the insulating layers 42. The first material layers 41A may be for forming a gate line. In an embodiment, the first material layers 41A may include a sacrificial material such as nitride, or may include a conductive material such as polysilicon or metal. The insulating layers 42 may be for insulating stacked gate lines from each other. In an embodiment, the insulating layers 42 may include an insulating material such as oxide or nitride, and may include a void therein.

Subsequently, a sacrificial contact structure 43 may be formed in the first stack ST1. In an embodiment, a first opening OP1 may be formed in the first stack ST1, and the sacrificial contact structure 43 may be formed in the first opening OP1. The first opening OP1 may be formed by etching the first stack ST1, and the first opening OP1 may have a taper shape according to a characteristic of an etching process. The first opening OP1 may extend from a front surface FS1 of the first stack ST1 toward a rear surface RS1. A lower width of the first opening OP1 may be narrower than an upper width. The sacrificial contact structure 43 may include a material with a high etch selectivity with respect to the first material layers 41A and the insulating layers 42. In an embodiment, the sacrificial contact structure 43 may include carbon, tungsten, and the like.

Subsequently, a second stack ST2 may be formed on the first stack ST1. The second stack ST2 may be formed by alternately stacking second material layers 41B and insulating layers 42 on the front surface FS1 of the first stack ST1. The second material layers 41B may include a material with a high etch selectivity with respect to the insulating layers 42. The second material layers 41B may be for forming gate lines. In an embodiment, the second material layers 41B may include a sacrificial material such as nitride, or may include a conductive material such as polysilicon or metal. The insulating layers 42 may be for insulating stacked gate lines from each other. In an embodiment, the insulating layers 42 may include an insulating material such as oxide or nitride, and may include a void therein.

Referring to FIG. 4B, the first stack ST1 and the second stack ST2 may be turned over so that the first stack ST1 is positioned on the second stack ST2. Through this, the rear surface RS1 of the first stack ST1 may be an upper surface, and a front surface FS2 of the second stack ST2 may be a lower surface. The first opening OP1 has an inverted taper shape.

Subsequently, the sacrificial contact structure 43 may be removed through the rear surface RS1 of the first stack ST1, e.g., by selective etching to form the first openings OP1 (reopened). A rear surface RS2 of the second stack ST2 may be exposed through the first openings OP1.

Referring to FIGS. 4C and 4D, the second stack ST2 may be etched through the first opening OP1, and a second opening OP2 may be formed in the second stack ST2. Through this, the first opening OP1 may be extended into the second stack ST2, and a contact hole CTH including the first opening OP1 in the first stack ST1 and the second opening OP2 in the second stack ST2 may be formed. The second opening OP2 may extend from the rear surface RS2 of the second stack ST2 toward the front surface FS2. The second opening OP2 may have a width in which a lower portion is less than an upper portion. The second opening OP2 may have a taper shape. When a plurality of first openings OP1 are formed, a plurality of second openings OP2 may be formed by respectively extending the first openings OP1. The second openings OP2 may extend in different depths and may expose the second material layers 41B, respectively.

First, referring to FIG. 4C, the second stack ST2 exposed through the first openings OP1 may be etched to form preliminary second openings OP2A. The preliminary second openings OP2A may have substantially the same depth. Subsequently, referring to FIG. 4D, the preliminary openings OP2A may be extended in different depths. Through this, the second openings OP2 respectively exposing the second material layers 41B may be formed.

Referring to FIG. 4E, a contact plug 45 may be formed in the first opening OP1 and the second opening OP2. After forming an insulating spacer 44 on an inner wall of the first opening OP1 and the second opening OP2, the contact plug 45 may be formed. The contact plug 45 may include a first portion 45A formed in the second opening OP2 and a second portion 45B formed in the first opening OP1. The first portion 45A may have a taper shape, and the second portion 45B may have an inverted taper shape.

For reference, before forming the contact plug 45, the first material layers 41A and the second material layers 41B may be replaced with third material layers 41C. The third material layers 4C may include a conductive material. Through this, the first stack ST1 and the second stack ST2 may be replaced with the gate structure GST. The gate structure GST including third material layers 41C and insulating layers 42 alternately stacked may be formed. In addition, the contact plugs 45 respectively connected to the third material layers 41C may be formed.

According to the manufacturing method described above, the first opening OP1 may be formed by etching the first stack ST1 to extend from the front surface FS1 toward the rear RS1. In addition, the second opening OP2 may be formed by etching the second stack ST2 to extend from the rear surface RS2 toward the front surface FS2. Therefore, an etching process may be performed in different directions, and the first opening OP1 and the second opening OP2 having taper shapes inverted from each other may be formed. As the contact hole CTH is formed by dividing the contact hole CTH with a large aspect ratio into the first opening OP1 and the second opening OP2, an etching depth may be reduced and a process cost may be reduced.

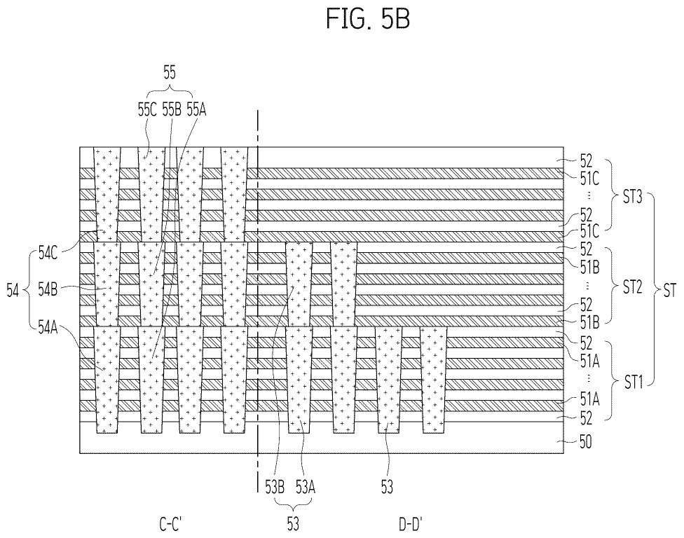

FIGS. 5A to 13A and 5B to 13B are simplified diagrams illustrating a method of manufacturing a semiconductor device according to an embodiment of the present disclosure. Hereinafter, any description that overlaps with what was described above may be omitted.

Referring to FIGS. 5A and 5B, a stack ST may be formed on a substrate 50 and sacrificial contact structures 53 may be formed in the stack ST. In an embodiment, a first stack ST1 may be formed by alternately stacking first material layers 51A and insulating layers 52, and first sacrificial layers 53A may be formed in the first stack ST1. Subsequently, a second stack ST2 may be formed by alternately stacking second material layers 51B and insulating layers 52, and second sacrificial layers 53B may be formed in the second stack ST2. The second sacrificial layers 53B may be connected to some of the first sacrificial layers 53A. Subsequently, a third stack ST3 may be formed by alternately stacking third material layers 51C and insulating layers 52.

Through this, first opening OP1 extending through the first stack ST1 and/or first opening OP1 extending through the first stack ST1 and the second stack ST2 may be formed. In addition, the sacrificial contact structures 53 may be formed in the first openings OP1. The sacrificial contact structures 53 may be positioned in the contact region CTR. The sacrificial contact structures 53 may have a taper shape or may have a structure in which the taper shape is repeated at least once.

Sacrificial slit structures 54 may be formed in the stack ST. In an embodiment, the first stack ST1 may be formed, and first sacrificial layers 54A may be formed in the first stack ST1. Subsequently, the second stack ST2 may be formed, and second sacrificial layer 54B connected to the first sacrificial layers 54A may be formed in the second stack ST2. Subsequently, the third stack ST3 may be formed, and third sacrificial layers 54C connected to the second sacrificial layers 54B may be formed in the third stack ST3.

Through this, third openings OP3 extending through the stack ST and sacrificial slit structures 54 in the third openings OP3 may be formed. When forming the sacrificial contact structures 53, the sacrificial slit structures 54 may be formed. The sacrificial slit structures 54 may be positioned in the cell region CR and the contact region CTR. The sacrificial slit structures 54 may have a structure in which a taper shape is repeated at least once.

Sacrificial channel structures 55 may be formed in the stack ST. In an embodiment, the first stack ST1 may be formed, and first sacrificial layers 55A may be formed in the first stack ST1. Subsequently, the second stack ST2 may be formed, and second sacrificial layer 55B connected to the first sacrificial layers 55A may be formed in the second stack ST2. Subsequently, a third stack ST3 may be formed, and third sacrificial layers 55C connected to the second sacrificial layers 55B may be formed in the third stack ST3.

Through this, channel holes CHH extending through the stack ST and the sacrificial channel structures 55 in the channel holes CHH may be formed. When forming the sacrificial contact structures 53, the sacrificial channel structures 55 may be formed. The sacrificial channel structures 55 may have a structure in which a taper shape is repeated at least once.

Sacrificial support structures 59 may be formed in the stack ST. The sacrificial support structures 59 may have a shape similar to that of the sacrificial channel structures 55. When forming the sacrificial channel structures 55, the sacrificial support structures 59 may also be formed. The sacrificial support structures 59 may have a structure in which a taper shape is repeated at least once.

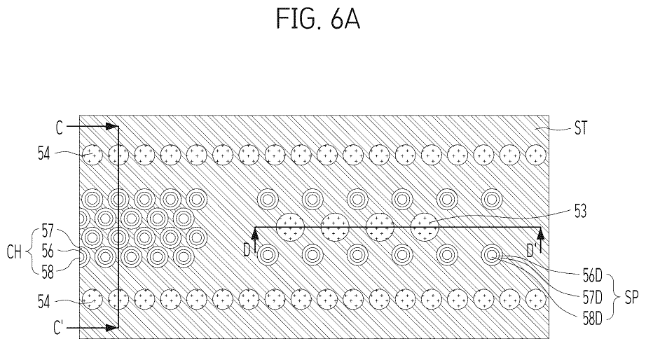

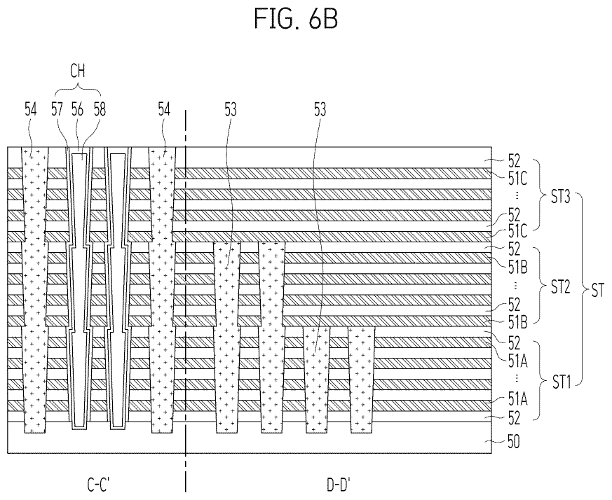

Referring to FIGS. 6A and 6B, the sacrificial channel structures 55 may be replaced with channel structures CH. A channel hole CHH may be formed (reopened) by selectively removing the sacrificial channel structures 55, and the channel structures CH may be formed in the channel holes CHH. Each of the channel structures CH may include a channel layer 56, a memory layer 57, and an insulating core 58.

When forming the channel structures CH, supports SP may also be formed. The supports SP may have a structure similar to that of the channel structures CH. In an embodiment, the supports SP may include a dummy channel layer 56D, a dummy memory layer 57D, and a dummy insulating core 58D.

Subsequently, although not shown in this drawing, an interconnection structure connected to channel structures CH and the like may be formed. In an embodiment, a bit line connected to channel structures CH may be formed.

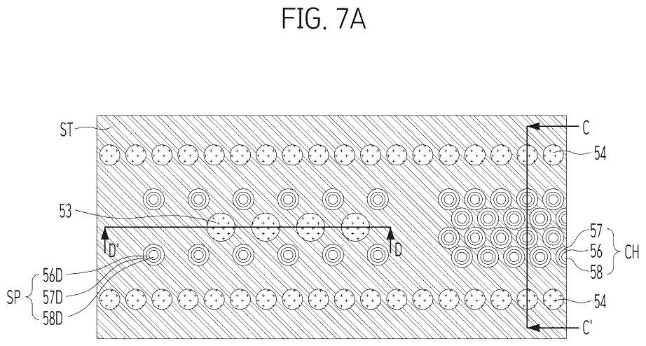

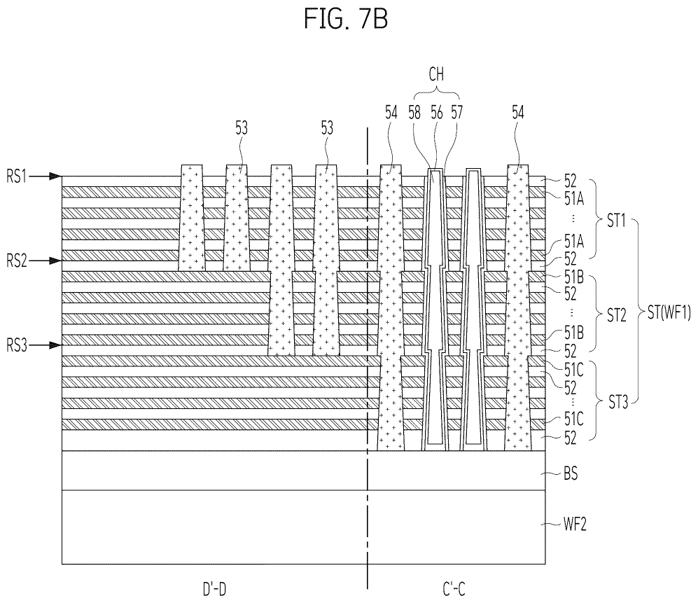

Referring to FIGS. 7A and 7B, a first wafer WF1 including the stack ST and the sacrificial contact structures 53 and a second wafer WF2 including a peripheral circuit may be bonded. The first wafer WF1 and the second wafer WF2 may be electrically connected through the bonding structure BS.

Subsequently, the substrate 50 may be removed to expose a rear surface RS1 of the first stack ST1. Through the rear surface RS1, the sacrificial contact structures 53, the sacrificial slit structures 54, and the channel structures CH may be exposed. Subsequently, the memory layers 57 may be etched to expose the channel layers 56. Subsequently, an impurity may be doped into the exposed channel layers 56.

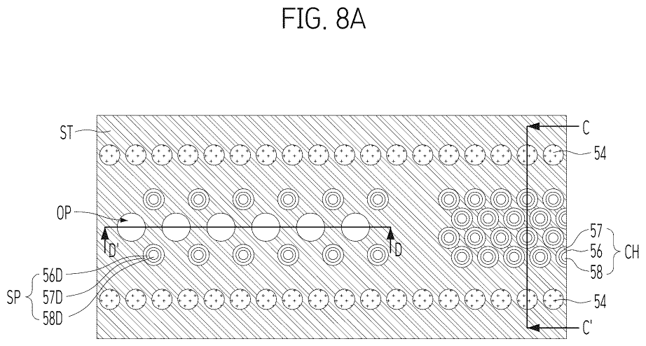

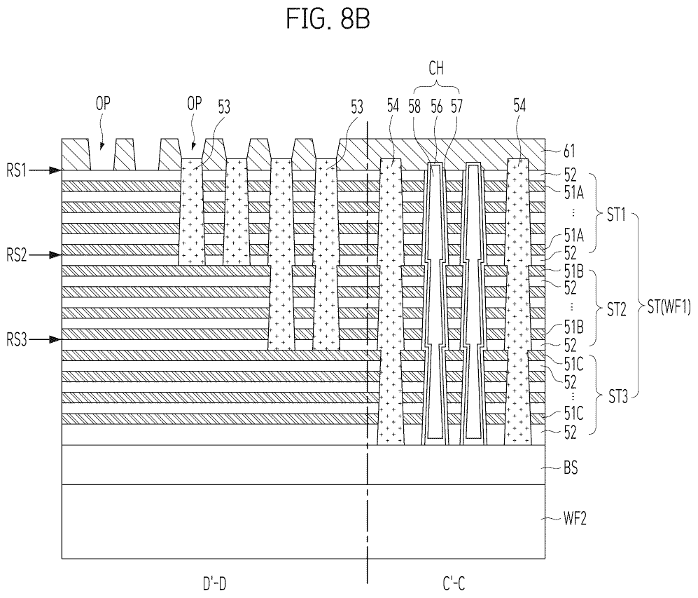

Referring to FIGS. 8A and 8B, a source structure 61 may be formed on the rear surface RS1 of the first stack ST1. The source structure 61 may include a conductive material such as polysilicon. Subsequently, openings OP extending through the source structure 61 may be formed. The openings OP may have a taper shape. The openings OP may expose the sacrificial contact structure 53 or may expose the rear surface RS1 of the first stack ST1. The opening OP exposing the rear surface RS1 may have a depth greater than that of the opening OP exposing the sacrificial contact structure 53.

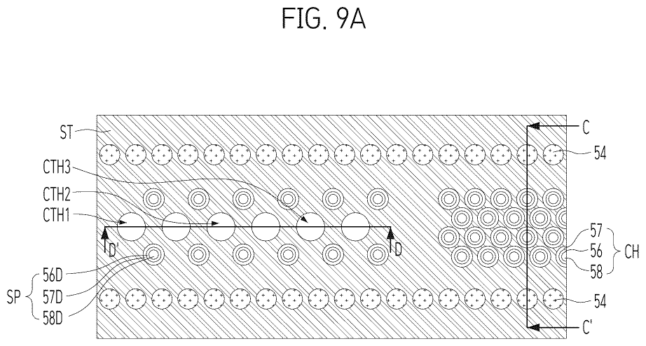

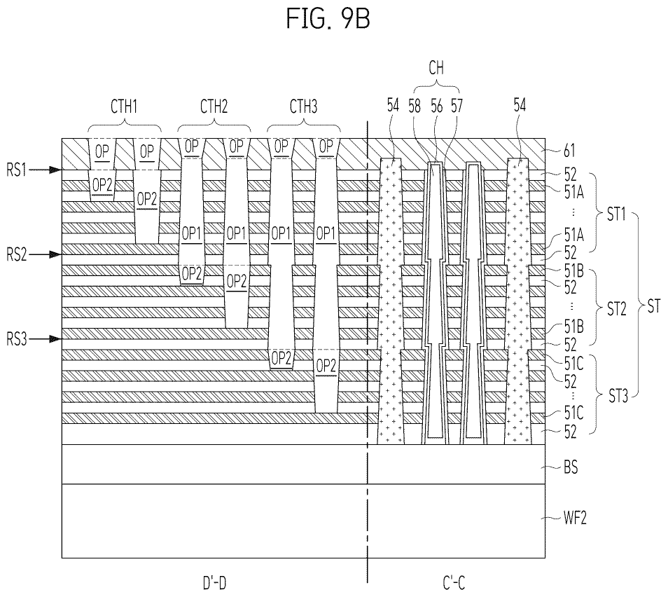

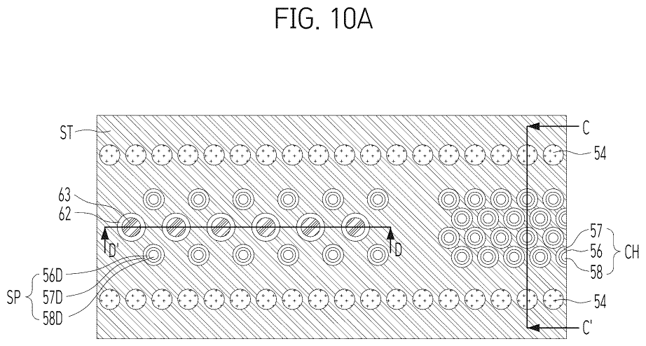

Referring to FIGS. 9A and 9B, the sacrificial contact structures 53 may be removed through the openings OP. Through this, the first openings OP1 may be formed (reopened). The reopened first openings OP1 may have an inverted taper shape. A rear surface RS2 of the second stack ST2 or a rear surface RS3 of the third stack ST3 may be exposed through the first openings OP1.

Subsequently, second openings OP2 may be formed. The second openings OP2 may have a taper shape. In an embodiment, after forming preliminary second openings having substantially the same depth, the preliminary second openings may be extended in different depths to form the second openings OP2 respectively exposing first to third material layers 51A to 51C.

The first stack ST1 may be etched through the openings OP to form the second openings OP2 extending into the first stack ST1. Through this, openings OP may extend into the first stack ST1. First contact holes CTH1 including the opening OP and the second opening OP2 and exposing the first material layers 51A may be formed. The first contact holes CTH1 having different depths to respectively expose the first material layers 51A may be formed. The first contact hole CTH1 may have a structure in which a taper shape is repeated at least once.

The second stack ST2 may be etched through the openings OP and the first openings OP1 to form the second openings OP2 extending into the second stack ST2. Through this, the first openings OP1 may extend into the second stack ST2. Second contact holes CTH2 including the openings OP, the first openings OP1, and the second openings OP2 and exposing the second material layers 51B may be formed. The second contact holes CTH2 having different depths to respectively expose the second material layers 51B may be formed. The second contact hole CTH2 may have a structure in which a taper shape and an inverted taper shape are combined.

The third stack ST3 may be etched through the openings OP and the first openings OP1 to form the second openings OP2 extending into the third stack ST3. Through this, the first openings OP1 may extend into the third stack ST3. Third contact holes CTH3 including the openings OP, the first openings OP1, and the second openings OP2 and exposing the third material layers 51C may be formed. The third contact holes CTH3 having different depths to respectively expose the third material layers 51C may be formed. The third contact hole CTH3 may have a structure in which a taper shape and an inverted taper shape are combined.

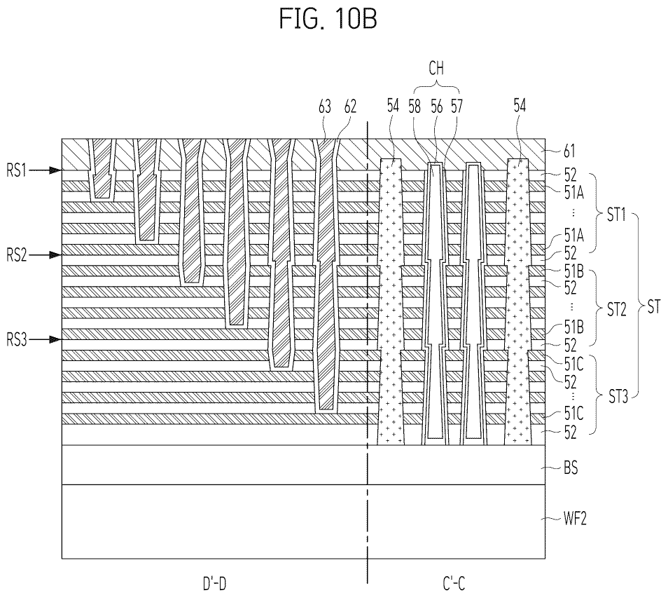

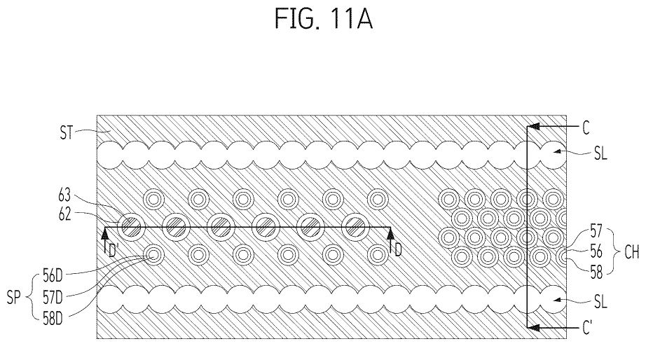

Referring to FIGS. 10A and 10B, insulating liners 62 and sacrificial layers 63 may be formed in the first to third contact holes CTH1 to CTH3. The insulating liners 62 may be formed along an inner surface of the first to third contact holes CTH1 to CTH3, and the sacrificial layers 63 may be formed to fill the first to third contact holes CTH1 to CTH3. Subsequently, the sacrificial layer 63 and the insulating liners 62 may be planarized until the source structure 61 is exposed. For example, the sacrificial layers 63 may include a material having an etch selectivity with respect to the insulating liners 62. In an embodiment, the sacrificial layers 63 may include tungsten and the insulating liners 62 may include oxide.

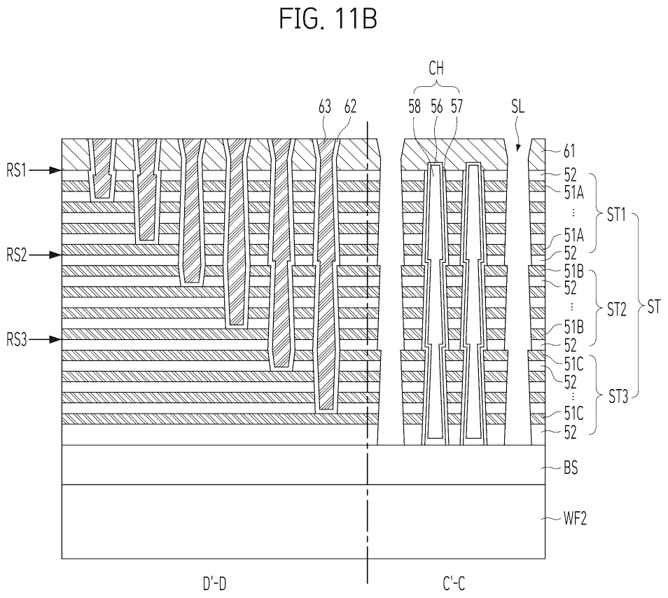

Referring to FIGS. 11A and 11B, the source structure 61 may be etched to expose the sacrificial slit structures 54. Subsequently, the sacrificial slit structures 54 may be removed through the rear surface RS1 of the first stack ST1 to form (reopen) the third openings OP3. Subsequently, the third openings OP3 may be expanded to form the slit SL. The first to third material layers 51A to 51C may be etched through the third openings OP3 and the insulating layers 52 may be etched to expand the third openings OP3. Through this, the third openings OP3 may be connected to each other, and the slit SL having an irregularity on a sidewall may be formed.

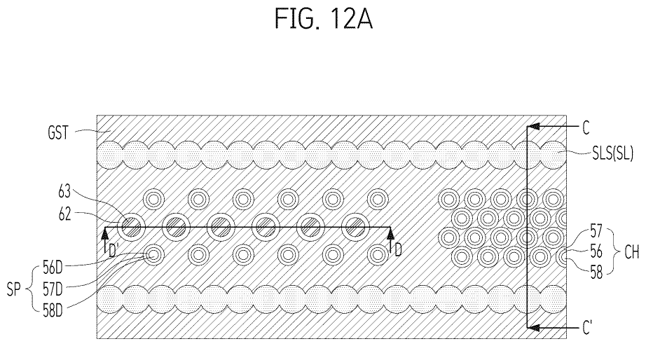

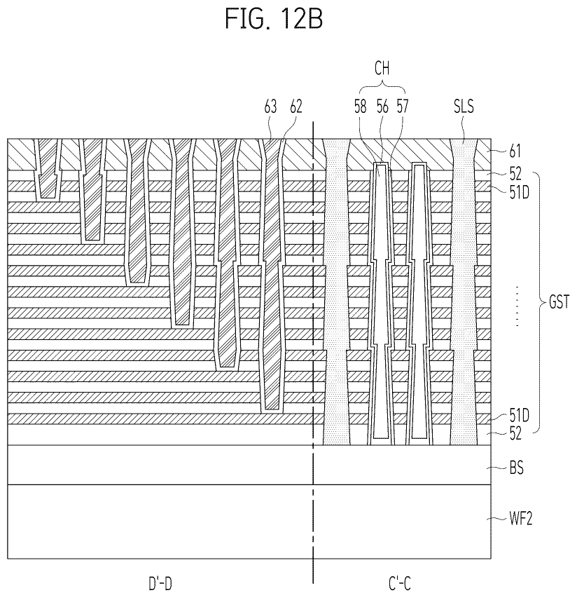

Referring to FIGS. 12A and 12B, the first to third material layers 51A to 51C may be replaced with fourth material layers 51D through the slit SL. In an embodiment, the first to third material layers 51A to 51C may be removed through the slit SL, and then the fourth material layers 51D may be formed. The fourth material layers 51D may form gate lines. In an embodiment, the fourth material layers 51D may include a conductive material and may include a metal such as tungsten (W) or molybdenum (Mo). Through this, a gate structure GST including the fourth material layers 51D and the insulating layers 52 alternately stacked may be formed.

Subsequently, a slit structure SLS may be formed in the slit SL. In an embodiment, the slit structure SLS may be a gap-fill layer including an insulating material, a semiconductor material, or the like.

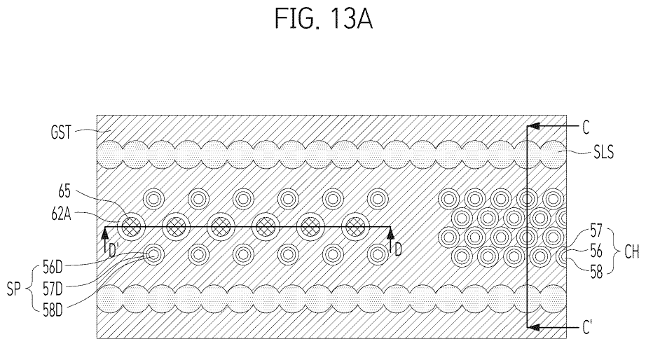

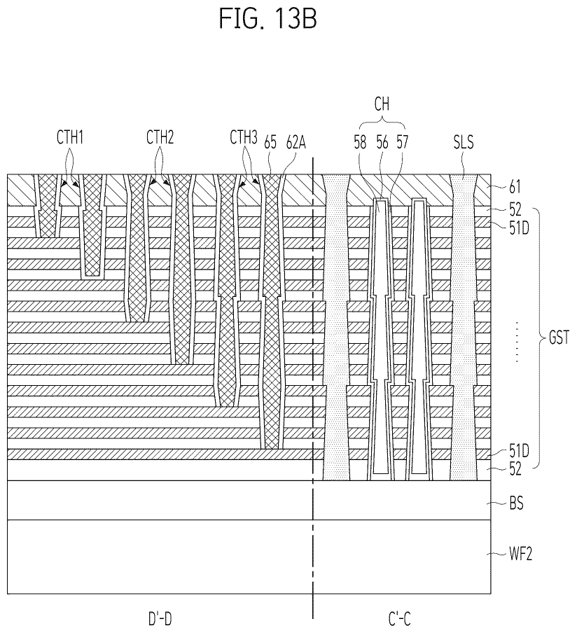

Referring to FIGS. 13A and 13B, the sacrificial layers 63 (shown in FIGS. 12A and 12B may be removed. Through this, the insulating liners 62 (shown in FIGS. 12A and 12B) may be exposed and the first to third contact holes CTH1 to CTH3 may be reopened, and, subsequently, the insulating liners 62 may be etched to form insulating spacers 62A on an inner wall of the first to third contact holes CTH1 to CTH3. Through this, the fourth material layers 51D may be exposed on a lower surface of the first to third contact holes CTH1 to CTH3. Subsequently, contact plugs 65 may be formed in the first to third contact holes CTH1 to CTH3 as shown in FIGS. 13A, and 13B. The contact plugs 65 may include a conductive layer comprising a conductive material such as tungsten.

According to the manufacturing method described above, in forming the first to third contact holes CTH1 to CTH3, a portion of each contact hole may be formed before performing a wafer bonding process, and a remaining portion of each contact hole may be formed after performing the wafer bonding process. Therefore, the process burden of forming contact holes with a large aspect ratio may be reduced. In addition, contact plugs 65 of a structure in which a taper shape and an inverted taper shape are combined may be formed.

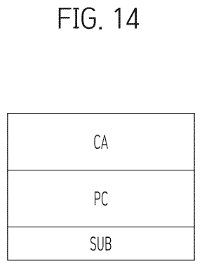

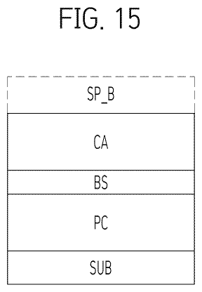

The structure and the manufacturing method according to the above-described embodiments may be applied to semiconductor devices of various structures. FIGS. 14 and 15 illustrate a schematic configuration of a semiconductor device to which the above-described embodiments may be applied.

FIG. 14 is a configuration diagram of a semiconductor device according to an embodiment of the present disclosure.

Referring to FIG. 14, the semiconductor device may include a substrate SUB, a peripheral circuit PC, and a memory cell array CA. For example, the peripheral circuit PC and the memory cell array CA may be formed on the same substrate.

The substrate SUB may include a semiconductor material. In an embodiment, the semiconductor material may include at least one of a group IV semiconductor, a group III-V compound semiconductor, and a group II-VI compound semiconductor. For example, the group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

In an embodiment, the substrate SUB may be a bulk wafer. In another embodiment, the substrate SUB may comprise an epitaxial layer grown, for example, on a bulk wafer substrate, using a selective epitaxial growth (SEG) method. For example, the substrate SUB may include an epitaxial layer of GaAs on a bulk wafer substrate of GaAs. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be positioned between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transmitting an operation voltage and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 15 is a configuration diagram of a semiconductor device according to an embodiment of the present disclosure.

Referring to FIG. 15, the semiconductor device may include a substrate SUB, a peripheral circuit PC, a bonding structure BS, and a memory cell array CA. For example, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after manufacturing each of a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may include any suitable material and/or structure for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal and/or an alloy of copper, aluminum, and the like. The bonding interface may include a non-metal-non-metal interface, a metal-metal interface, or the like. The memory cell array CA and the peripheral circuit PC may be electrically connected by the bonding structure BS.

For reference, an interconnection structure included in the cell array CA and/or the peripheral circuit PC may be directly connected without a bonding pad. In an embodiment, a bonding layer included in the cell array CA and a bonding layer included in the peripheral circuit PC may be bonded to form the bonding interface, and an interconnection structure included in the cell array CA and an interconnection structure included in the peripheral circuit PC may be directly connected. Through this, contact plugs, lines, and the like formed on different wafers may be electrically connected without a separate bonding pad.

Other configurations may be equal or similar to those previously described with reference to FIG. 14.

The semiconductor device may have a structure in which the embodiments described above with reference to FIGS. 14 and 15 are combined or may have a partially modified structure. In the embodiments described with reference to FIGS. 14 and 15, positions of the memory cell array CA and the peripheral circuit PC may be changed. At least one memory cell array CA and/or at least one peripheral circuit PC may be additionally bonded to the embodiment described with reference to FIG. 14. In an embodiment, a portion of the peripheral circuitry PC may be positioned in the memory cell array CA.

Although embodiments according to the technical concepts of the present disclosure have been described with reference to the accompanying drawings, this is only for describing an embodiment according to the concept of the present disclosure, and the embodiments of the present disclosure are not limited to the above-described embodiments. Within the scope of the present disclosure, various forms of substitution, modification, change, and combination of the embodiments may be envisioned by those skilled in the art to which the present disclosure belongs. Furthermore, the embodiments may be combined to form additional embodiments.

What is claimed is:

1. A semiconductor device comprising:
a gate structure including a plurality of gate lines;
a first contact plug extending through the gate structure, the first contact plug being electrically connected to a first gate line among the gate lines, and including a first portion having a taper shape and a second portion having an inverted taper shape; and
a second contact plug extending through the gate structure, electrically connected to a second gate line among the gate lines, and having a taper shape.

2. The semiconductor device of claim 1, wherein the first contact plug includes a connect surface where the first portion and the second portion are connected, wherein a width of the first portion and the second portion decreases as a distance from the connect surface increases.

3. The semiconductor device of claim 1, wherein an upper surface of the first portion and a lower surface of the second portion are connected.

4. The semiconductor device of claim 1, wherein an inverted taper shape is repeated in the second portion, and the second portion includes a step on a sidewall.

5. The semiconductor device of claim 1, further comprising:
a source structure disposed on the gate structure.

6. The semiconductor device of claim 5, wherein the first contact plug includes a third portion extending through the source structure and having a taper shape.

7. The semiconductor device of claim 5, wherein the second portion protrudes into the source structure.

8. The semiconductor device of claim 5, further comprising:
a channel structure extending into the source structure through the gate structure and having an inverted taper shape.

9. The semiconductor device of claim 5, further comprising:
a slit structure including a first portion extending through the gate structure and having an inverted taper shape and a second portion extending through the source structure and having a taper shape.

10. The semiconductor device of claim 1, wherein the first contact plug has a height greater than that of the second contact plug.

11. The semiconductor device of claim 1, further comprising:
a first insulating spacer surrounding a sidewall of the first contact plug; and
a second insulating spacer surrounding a sidewall of the second contact plug.

12. A semiconductor device comprising:
a gate structure including stacked gate lines;
a source structure disposed on the gate structure; and
a first contact plug extending through the gate structure and the source structure, the first contact plug being electrically connected to a first gate line among the gate lines,
wherein the first contact plug comprises:
a first portion extending through the gate structure and having a taper shape;
a second portion extending through the gate structure and having an inverted taper shape; and
a third portion extending through the source structure and having a taper shape.

13. The semiconductor device of claim 12, wherein the second portion is connected between the first portion and the third portion.

14. The semiconductor device of claim 12, wherein an inverted taper shape is repeated in the second portion, and the second portion includes a step on a sidewall.

15. The semiconductor device of claim 12, further comprising:
a second contact plug extending through the source structure and the gate structure, electrically connected to a second gate line among the gate lines, and having a repeated taper shape.

16. The semiconductor device of claim 12, further comprising:
a channel structure extending into the source structure through the gate structure and having an inverted taper shape.

17. The semiconductor device of claim 12, further comprising:
a slit structure including a first portion extending through the gate structure and having an inverted taper shape and a second portion extending through the source structure and having a taper shape.
